(19) United States
(12) Patent Application Publication
(10) Pub. No.: US 2015/0050504 A1
(43) Pub. Date: Feb. 19, 2015

(54) CORE SUBSTRATE AND METHOD OF MANUFACTURING THE SAME

(71) Applicant: SAMSUNG ELECTRO-MECHANICS CO., LTD., Suwon-si (KR)

(72) Inventors: Sa Yong Lee, Suwon-si (KR); Keun Yong Lee, Suwon-si (KR)

(73) Assignee: SAMSUNG ELECTRO-MECHANICS CO., LTD., Suwon-si (KR)

(21) Appl. No.: 14/170,359

(22) Filed: Jan. 31, 2014

(30) Foreign Application Priority Data
Aug. 14, 2013 (KR) 10-2013-0096812

(51) Int. Cl. H05K 1/03; H05K 3/46; H05K 1/02

(52) U.S. Cl. CPC H05K 1/0306; H05K 1/0271; H05K 3/4691
USPC 428/426; 156/306.6

(57) ABSTRACT

Disclosed herein are a core substrate and a method of manufacturing the same. The core substrate includes: a glass substrate made of an insulating material and a photosensitive insulating layer formed on at least one of one surface and the other surface of the glass substrate. With the core substrate and the method of manufacturing the same, fine circuit patterns may be formed and generation of a defect such as separation of a circuit pattern may be decreased.

### CROSS REFERENCE TO RELATED APPLICATION

This application claims the benefit of Korean Patent Application No. 10-2013-0096812, filed on Aug. 14, 2013, entitled “Core Substrate and Method of Manufacturing the Same”, which is hereby incorporated by reference in its entirety into this application.

### BACKGROUND OF THE INVENTION

1. Technical Field

The present invention relates to a core substrate and a method of manufacturing the same.

2. Description of the Related Art

In accordance with development of an electronic device, lightness, thinness, and miniaturization of a printed circuit board have been gradually conducted. In order to satisfy these demands, a wiring of a printed circuit has been complicated and densified. In addition, electrical, thermal, and mechanical characteristics demanded in the printed circuit board have acted as more important elements. The printed circuit board is mainly configured of an electrical conductive metal such as copper serving as a circuit wiring and a polymer serving as an interlayer dielectric. In the polymer configuring the insulating layer, several characteristics such as a coefficient of thermal expansion, a glass transition temperature, thickness non-uniformity, a thin thickness, and the like, are demanded, as compared with copper. As the circuit board is thinned, thickness quality of the circuit board is unstable, such that characteristics such as a coefficient of thermal expansion, a dielectric constant, a dielectric loss, and the like, are deteriorated, and a phenomenon that the circuit board is warped at the time of mounting components on the circuit board and a signal transmission defect in a high frequency region may be generated. In order to prevent the phenomenon that the circuit board is warped, a method of stacking a build-up layer by introducing a copper clad laminate having a thick thickness onto the circuit board has been used (US Patent Laid-Open Publication No. 2006-0191709). Since close adhesion between the copper clad laminate according to the prior art and circuit patterns is low, stability in forming circuits is low. Further, in accordance with densification and thinness of the circuit board, it is difficult to form circuit patterns having a fine pitch of about nanometer to micrometer.

### SUMMARY OF THE INVENTION

The present invention has been made in an effort to provide a core substrate capable of forming fine circuit patterns, and a method of manufacturing the same.

Further, the present invention has been made in an effort to provide a core substrate capable of decreasing generation of a defect such as separation of circuit patterns, and a method of manufacturing the same.

Further, the present invention has been made in an effort to provide a core substrate capable of decreasing a thickness deviation, and a method of manufacturing the same.

Further, the present invention has been made in an effort to provide a core substrate capable of decreasing warpage, and a method of manufacturing the same.

According to a preferred embodiment of the present invention, there is provided a core substrate including: a glass substrate having flexibility; and a photosensitive insulating layer formed on at least one of one surface and the other surface of the glass substrate.

The glass substrate may not transmit light therethrough.

The core substrate may further include a protective layer formed on one surface or the other surface of the photosensitive insulating layer.

The core substrate may further include a primer layer formed between the glass substrate and the photosensitive insulating layer.

According to another preferred embodiment of the present invention, there is provided a method of manufacturing a core substrate, including: supplying a glass substrate having flexibility by a first supplying roller; supplying a photosensitive insulating layer onto at least one of one surface and the other surface of the glass substrate by a second supplying roller; and compressing the photosensitive insulating layer onto the glass substrate by a first compressing roller.

In the supplying of the glass substrate, the glass substrate may not transmit light therethrough.

In the supplying of the photosensitive insulating layer, the photosensitive insulating layer may include a protective layer formed on one surface or the other surface thereof.

The photosensitive insulating layer may be formed beneath the protective layer by a casting method.

The method may further include, after the compressing of the photosensitive insulating layer onto the glass substrate, supplying a protective layer onto one surface or the other surface of the photosensitive insulating layer by a third supplying roller.

The method may further include, after the supplying of the protective layer onto one surface or the other surface of the photosensitive insulating layer, compressing the protective layer onto the photosensitive insulating layer by a second compressing roller.

The method may further include, after the supplying of the glass substrate, supplying a primer layer onto one surface or the other surface of the glass substrate by a fourth supplying roller.

The method may further include, after the supplying of the primer layer, compressing the primer layer onto the glass substrate by a third compressing roller.

According to still another preferred embodiment of the present invention, there is provided a core substrate including: a glass substrate having flexibility; and a primer layer formed on at least one of one surface and the other surface of the glass substrate.

The glass substrate may not transmit light therethrough.

The core substrate may further include a protective layer formed on one surface or the other surface of the primer layer.

The core substrate may further include a photosensitive insulating layer formed on one surface or the other surface of the primer layer.

The core substrate may further include a protective layer formed on one surface or the other surface of the photosensitive insulating layer.

According to yet still another preferred embodiment of the present invention, there is provided a method of manufacturing a core substrate, including: supplying a glass substrate having flexibility by a first supplying roller; supplying a primer layer onto at least one of one surface and the other surface of the glass substrate by a second supplying roller; and compressing the primer layer onto the glass substrate by a first compressing roller.

In the supplying of the glass substrate, the glass substrate may not transmit light therethrough.

In the supplying of the primer layer, the primer layer may include a protective layer formed on one surface or the other surface thereof.

The primer layer may be formed beneath the protective layer by a casting method.

The method may further include, after the compressing of the primer layer onto the glass substrate, supplying a protective layer onto one surface or the other surface of the primer layer by a third supplying roller.

The method may further include, after the supplying of the protective layer onto one surface or the other surface of the primer layer, compressing the protective layer onto the primer layer by a second compressing roller.

The method may further include, after the compressing of the primer layer onto the glass substrate, supplying a photosensitive insulating layer onto one surface or the other surface of the primer layer by a fourth supplying roller.

The method may further include, after the supplying of the photosensitive insulating layer, compressing the photosensitive insulating layer onto the primer layer by a third compressing roller.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an illustrative view showing a core substrate according to a first preferred embodiment of the present invention;

FIG. 2 is an illustrative view showing a method of manufacturing a core substrate according to the first preferred embodiment of the present invention;

FIG. 3 is an illustrative view showing a core substrate according to a second preferred embodiment of the present invention;

FIG. 4 is an illustrative view showing a method of manufacturing a core substrate according to the second preferred embodiment of the present invention;

FIG. 5 is an illustrative view showing another method of manufacturing a core substrate according to the second preferred embodiment of the present invention;

FIG. 6 is an illustrative view showing a core substrate according to a third preferred embodiment of the present invention;

FIG. 7 is an illustrative view showing a method of manufacturing a core substrate according to the third preferred embodiment of the present invention;

FIG. 8 is an illustrative view showing a core substrate according to a fourth preferred embodiment of the present invention;

FIG. 9 is an illustrative view showing a method of manufacturing a core substrate according to the fourth preferred embodiment of the present invention;

FIG. 10 is an illustrative view showing another method of manufacturing a core substrate according to the fourth preferred embodiment of the present invention;

FIG. 11 is an illustrative view showing a core substrate according to a fifth preferred embodiment of the present invention; and

FIG. 12 is an illustrative view showing a method of manufacturing a core substrate according to the fifth preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

### First Preferred Embodiment

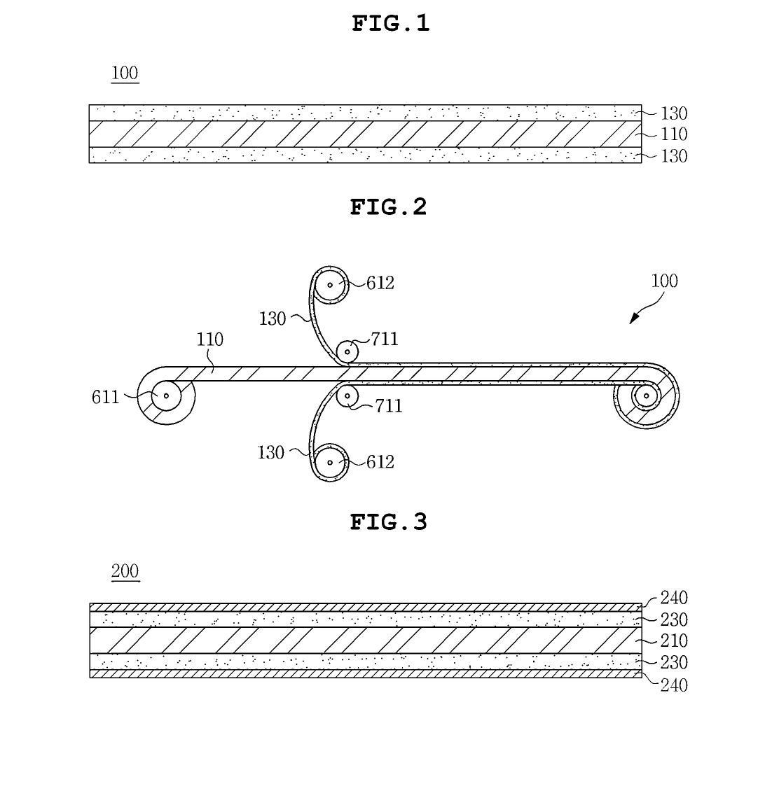

FIG. 1 is an illustrative view showing a core substrate according to a first preferred embodiment of the present invention.

Referring to FIG. 1, the core substrate 100 may be configured to include a glass substrate 110 and a photosensitive insulating layer 130.

The glass substrate 110 may have flexibility. Since the glass substrate 110 has the flexibility, when the photosensitive insulating layer 130 is formed on the glass substrate 110, a roll-to-roll method may be used. In addition, the glass substrate 110 may be a glass plate through which light is not transmitted. The glass substrate 110 may be hardly transparent so as not to transmit the light therethrough when an exposure process will be performed later in order to pattern the photosensitive insulating layer 130. The glass substrate 110 may serve to insulate between circuit patterns (not shown) to be formed later. Rigidity of the glass substrate 110 is high and a deformation degree thereof depending on temperature and humidity changes is low.

Therefore, warpage of a printed circuit board including the core substrate 100 and a build-up layer formed on the core substrate 100 may be decreased by the glass substrate 110. In addition, since the glass substrate 110 has flexibility, it has low brittleness, such that it is hardly broken by external impact. Further, the flexible glass substrate 110 may be applied to a printed circuit board having a curved surface.

The photosensitive insulating layer 130 may be formed on at least one of one surface and the other surface of the glass substrate 110. Although the case in which the photosensitive insulating layers 130 are formed on both surfaces of the glass substrate 110 has been described in the first preferred embodiment of the present invention, the present invention is not limited thereto. That is, the photosensitive insulating layer 130 may also be formed on only one of one surface and the other surface of the glass substrate 110.

The photosensitive insulating layer 130 may be a positive type photosensitive insulating layer. In the positive type photosensitive insulating layer 130, photopolymer polymer bonding in a region in which light is received in an exposure process is broken down. When a development process is performed on the positive type photosensitive insulating layer 130 after the exposure process, a portion at which the photopolymer polymer bonding is broken down is removed, such that the positive type photosensitive insulating layer 130 may be patterned.

In addition, the photosensitive insulating layer 130 may be a negative type photosensitive insulating layer. In the negative type photosensitive insulating layer 130, a photopolymerization reaction is generated in a portion at which light is received in the exposure process to form a three-dimensional network structure having a chain structure from a single structure, and the portion at which the light is received is cured. When the development process is performed on the negative type photosensitive insulating layer 130 after the exposure process, a region that is not cured is removed, such that the negative type photosensitive insulating layer 130 may be patterned.

In the core substrate 100 according to the first preferred embodiment of the present invention, circuit patterns are formed later in the photosensitive insulating layer 130 in a form in which they are buried in the photosensitive insulating layer 130, thereby making it possible to decrease a defect such as undercut of the circuit pattern, separation of the circuit pattern, or the like.

FIG. 2 is an illustrative view showing a method of manufacturing a core substrate according to the first preferred embodiment of the present invention.

Referring to FIG. 2, the core substrate 100 according to the first preferred embodiment of the present invention may be formed using a roll-to-roll device.

The roll-to-roll device according to the preferred embodiment of the present invention may include a first supplying roller 611, a second supplying roller 612, and a first compressing roller 711.

First, the glass substrate 110 may be supplied by the first supplying roller 611. The glass substrate 110 is a glass plate having flexibility. In addition, the glass substrate 110 may be a glass plate through which light is not transmitted. That is, the glass substrate 110 may be hardly transparent so as not to transmit the light therethrough when an exposure process will be performed later in order to pattern the photosensitive insulating layer 130.

The glass substrate 110 may be continuously supplied in the roll-to-roll device by the first supplying roller 611. According to the preferred embodiment of the present invention, since the glass substrate 110 is flexible, it is appropriate for a roll-to-roll process.

After the glass substrate 110 is supplied by the first supplying roller 611, the photosensitive insulating layer 130 may be supplied by the second supplying roller 612. Here, the photosensitive insulating layer 130 may be supplied onto at least one of one surface and the other surface of the glass substrate 110. According to the preferred embodiment of the present invention, the second supplying roller 612 may supply the photosensitive insulating layers 130 onto both surfaces of the glass substrate 110. The photosensitive insulating layer 130 may be a positive type photosensitive insulating layer in which a region subjected to exposure is decomposed. Alternatively, the photosensitive insulating layer 130 may be a negative type photosensitive insulating layer in which a region subjected to exposure is cured.

After the photosensitive insulating layer 130 is supplied onto the glass substrate 110, it may be compressed onto the glass substrate 110. The compression of the photosensitive insulating layer 130 onto the glass substrate 110 may be performed by the first compressing roller 711. The photosensitive insulating layer 130 is compressed onto the glass substrate 110 by the first compressing roller 711, such that the core substrate 100 according to the first preferred embodiment of the present invention may be formed.

As described above, the roll-to-roll device and the roll-to-roll method are used, thereby making it possible to easily form fine circuit patterns and the core substrate 100 according to the first preferred embodiment of the present invention having a small thickness deviation.

### Second Preferred Embodiment

FIG. 3 is an illustrative view showing a core substrate according to a second preferred embodiment of the present invention.

Referring to FIG. 3, the core substrate 200 may be configured to include a glass substrate 210, a photosensitive insulating layer 230, and a protective layer 240.

The core substrate 200 according to the second preferred embodiment of the present invention may be a base on which an insulating layer and a circuit layer are formed.

The glass substrate 210 may have flexibility. Since the glass substrate 210 has the flexibility, when the photosensitive insulating layer 230 is formed on the glass substrate 210, a roll-to-roll method may be used. In addition, the glass substrate 210 may be a glass plate through which light is not transmitted. The glass substrate 210 may be hardly transparent so as not to transmit the light therethrough when an exposure process will be performed later in order to pattern the photosensitive insulating layer 230. The glass substrate 210 may serve to insulate between circuit patterns (not shown) to be formed later.

The photosensitive insulating layer 230 may be formed on at least one of one surface and the other surface of the glass substrate 210. Although the case in which the photosensitive insulating layers 230 are formed on both surfaces of the glass substrate 210 has been described in the second preferred embodiment of the present invention, the present invention is not limited thereto. That is, the photosensitive insulating layer 230 may also be formed on only one of one surface and the other surface of the glass substrate 210.

The photosensitive insulating layer 230 may be a positive type photosensitive insulating layer in which a region subjected to exposure is decomposed. Alternatively, the photosensitive insulating layer 230 may be a negative type photosensitive insulating layer in which a region subjected to exposure is cured.

The protective layer 240 may be formed on one surface or the other surface of the photosensitive insulating layer 230. The protective layer 240 may protect the photosensitive insulating layer 230 from a stab due to a process to be performed later or foreign materials. According to the preferred embodiment of the present invention, a surface of the protective layer 240 bonded to the photosensitive insulating layer 230 may have a surface roughness smaller than that of the photosensitive insulating layer 230. The surface roughness of the photosensitive insulating layer 230 may be decreased by the protective layer 240 having the small surface roughness. Therefore, when a process of removing the protective layer 240 and forming circuit patterns will be performed later, fine circuit patterns may be implemented by the small surface roughness of the photosensitive insulating layer 230. For example, the protective layer 240 may be formed of a polyimide film or a polyethylene terephthalate (PET) film. However, a material of the protective layer 240 is not limited thereto, but may be easily changed and applied by those skilled in the art as long as it may protect the photosensitive insulating layer 230.

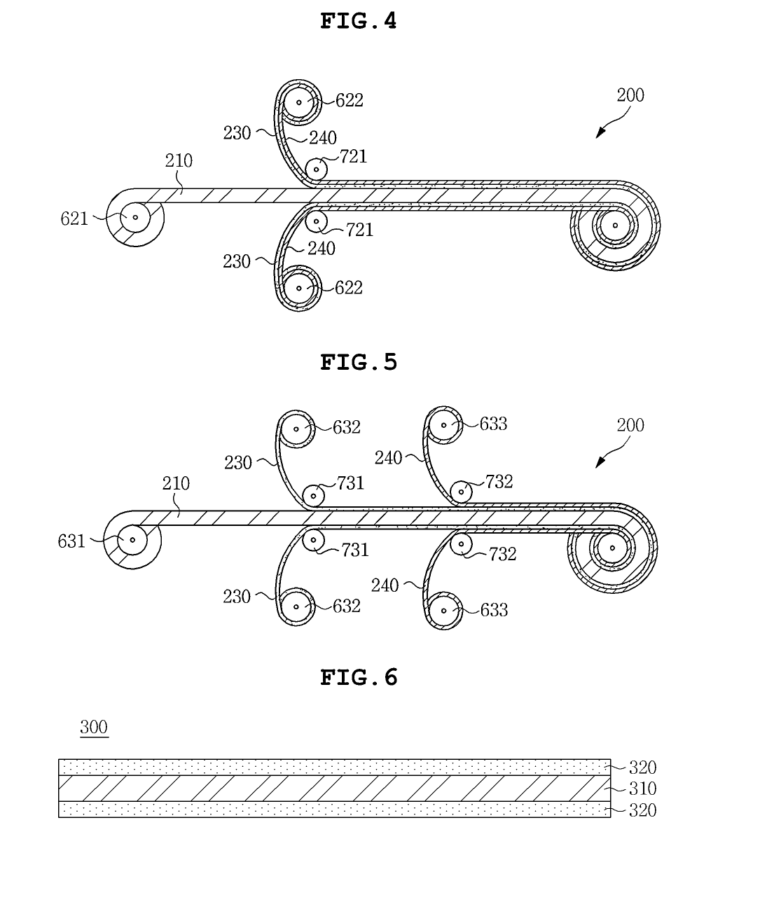

FIG. 4 is an illustrative view showing a method of manufacturing a core substrate according to the second preferred embodiment of the present invention.

Referring to FIG. 4, the core substrate 200 of FIG. 3 may be formed using a roll-to-roll device.

The core substrate 200 may be manufactured by the roll-to-roll device. The roll-to-roll device according to the preferred embodiment of the present invention may include a first supplying roller 621, a second supplying roller 622, and a first compressing roller 721.

First, the glass substrate 210 may be supplied by the first supplying roller 621. The glass substrate 210 is a glass plate having flexibility. In addition, the glass substrate 210 may be a glass plate through which light is not transmitted. That is, the glass substrate 210 may be hardly transparent so as not to transmit the light therethrough when an exposure process will be performed later in order to pattern the photosensitive insulating layer 230.

The glass substrate 210 may be continuously supplied in the roll-to-roll device by the first supplying roller 621. According to the preferred embodiment of the present invention, since the glass substrate 210 is flexible, it is appropriate for a roll-to-roll process.

After the glass substrate 210 is supplied by the first supplying roller 621, the photosensitive insulating layer 230 may be supplied by the second supplying roller 622. The photosensitive insulating layer 230 may be supplied onto at least one of one surface and the other surface of the glass substrate 210. According to the preferred embodiment of the present invention, the second supplying roller 622 may supply the photosensitive insulating layers 230 onto both surfaces of the glass substrate 210. The photosensitive insulating layer 230 may be a positive type photosensitive insulating layer in which a region subjected to exposure is decomposed. Alternatively, the photosensitive insulating layer 230 may be a negative type photosensitive insulating layer in which a region subjected to exposure is cured.

After the photosensitive insulating layer 230 is supplied onto the glass substrate 210, it may be compressed onto the glass substrate 210. The compression of the photosensitive insulating layer 230 onto the glass substrate 210 may be performed by the first compressing roller 721.

In the preferred embodiment of the present invention, the protective layer 240 may be provided on one surface or the other surface of the photosensitive insulating layer 230. The protective layer 240 may prevent the photosensitive insulating layer 230 from being damaged due to a process to be performed later or foreign materials. According to the preferred embodiment of the present invention, the protective layer 240 may have a surface roughness smaller than that of the photosensitive insulating layer 230. The protective layer 240 having the small surface roughness may be attached to the photosensitive insulating layer 230 to allow the photosensitive insulating layer 230 to have a small surface roughness. Therefore, when circuit patterns will be formed later, fine circuit patterns may be implemented by the small surface roughness of the photosensitive insulating layer 230. The photosensitive insulating layer 230 according to the second preferred embodiment of the present invention may be formed beneath the protective layer 240 by a casting method.

For example, the protective layer 240 may be formed of a polyimide film or a PET film. However, a material of the protective layer 240 is not limited thereto. That is, a material of the protective layer 240 may be easily changed and applied by those skilled in the art as long as it may protect the photosensitive insulating layer 230. The protective layer 240 may be formed on an opposite surface to a surface of the photosensitive insulating layer 230 contacting the glass substrate 210.

After the photosensitive insulating layer 230 having the protective layer 240 formed thereon is supplied onto the glass substrate 210, it may be compressed onto the glass substrate 210. The compression of the protective layer 240 and the photosensitive insulating layer 230 onto the glass substrate 210 may be performed by the first compressing roller 721.

As described above, the roll-to-roll device and the roll-to-roll method are used, thereby making it possible to easily form fine circuit patterns and the core substrate 200 according to the second preferred embodiment of the present invention having a small thickness deviation.

FIG. 5 is an illustrative view showing another method of manufacturing a core substrate according to the second preferred embodiment of the present invention.

Referring to FIG. 5, the core substrate 200 of FIG. 3 may be formed using a roll-to-roll device.

The roll-to-roll device according to the preferred embodiment of the present invention may include a first supplying roller 631, a second supplying roller 632, a third supplying roller 633, a first compressing roller 731, and a second compressing roller 732.

First, the glass substrate 210 may be supplied by the first supplying roller 631. The glass substrate 210 is a glass plate having flexibility. In addition, the glass substrate 210 may be a glass plate through which light is not transmitted. That is, the glass substrate 210 may be hardly transparent so as not to transmit the light therethrough when an exposure process will be performed later in order to pattern the photosensitive insulating layer 230.

After the glass substrate 210 is supplied by the first supplying roller 631, the photosensitive insulating layer 230 may be supplied by the second supplying roller 632. Here, the photosensitive insulating layer 230 may be supplied onto at least one of one surface and the other surface of the glass substrate 210. According to the preferred embodiment of the present invention, the second supplying roller 632 may supply the photosensitive insulating layers 230 onto both surfaces of the glass substrate 210. The photosensitive insulating layer 230 may be a positive type photosensitive insulating layer in which a region subjected to exposure is decomposed. Alternatively, the photosensitive insulating layer 230 may be a negative type photosensitive insulating layer in which a region subjected to exposure is cured.

After the photosensitive insulating layer 230 is supplied onto the glass substrate 210, it may be compressed onto the glass substrate 210. The compression of the photosensitive insulating layer 230 onto the glass substrate 210 may be performed by the first compressing roller 731.

After the photosensitive insulating layer 230 is compressed onto the glass substrate 210, the protective layer 240 may be supplied onto one surface or the other surface of the photosensitive insulating layer 230. The protective layer 240 may be supplied by the third supplying roller 633. The protective layer 240 may prevent the photosensitive insulating layer 230 from being damaged due to a process to be performed later or foreign materials. According to the preferred embodiment of the present invention, the protective layer 240 may have a surface roughness smaller than that of the photosensitive insulating layer 230. The protective layer 240 having the small surface roughness may be attached to the photosensitive insulating layer 230 to allow the photosensitive insulating layer 230 to have a small surface roughness. For example, the protective layer 240 may be formed of a polyimide film or a PET film. However, a material of the protective layer 240 is not limited thereto, but may be easily changed and applied by those skilled in the art as long as it may protect the photosensitive insulating layer 230.

When the protective layer 240 is supplied onto one surface or the other surface of the photosensitive insulating layer 230, the protective layer 240 may be compressed onto the photosensitive insulating layer 230 by the second compressing roller 732.

As described above, the roll-to-roll device and the roll-to-roll method are used, thereby making it possible to easily form fine circuit patterns and the core substrate 200 according to the second preferred embodiment of the present invention having a small thickness deviation.

### Third Preferred Embodiment

FIG. 6 is an illustrative view showing a core substrate according to a third preferred embodiment of the present invention.

Referring to FIG. 6, the core substrate 300 may be configured to include a glass substrate 310 and a primer layer 320.

The glass substrate 310 may have flexibility. Since the glass substrate 310 has the flexibility, when a photosensitive insulating layer 330 is formed on the glass substrate 310, a roll-to-roll method may be used. The glass substrate 310 may serve to insulate between circuit patterns (not shown) to be formed later. Rigidity of the glass substrate 310 is high and a deformation degree thereof depending on temperature and humidity changes is low. Therefore, warpage of a printed circuit board including the core substrate 300 and a build-up layer formed on the core substrate 300 may be decreased by the glass substrate 310. In addition, since the glass substrate 310 has flexibility, it has low brittleness, such that it is hardly broken by external impact. Further, the flexible glass substrate 310 may be applied to a printed circuit board having a curved surface.

The primer layer 320 may be formed on at least one of one surface and the other surface of the glass substrate 310. Although the case in which the primer layers 320 are formed on both surfaces of the glass substrate 310 has been described in the third preferred embodiment of the present invention, the present invention is not limited thereto. That is, the primer layer 320 may also be formed on only one of one surface and the other surface of the glass substrate 310.

Since the primer layer 320 has excellent adhesion, when circuit patterns will be formed later on the core substrate 300, adhesion between the core substrate 300 and the circuit patterns (not shown) may be improved.

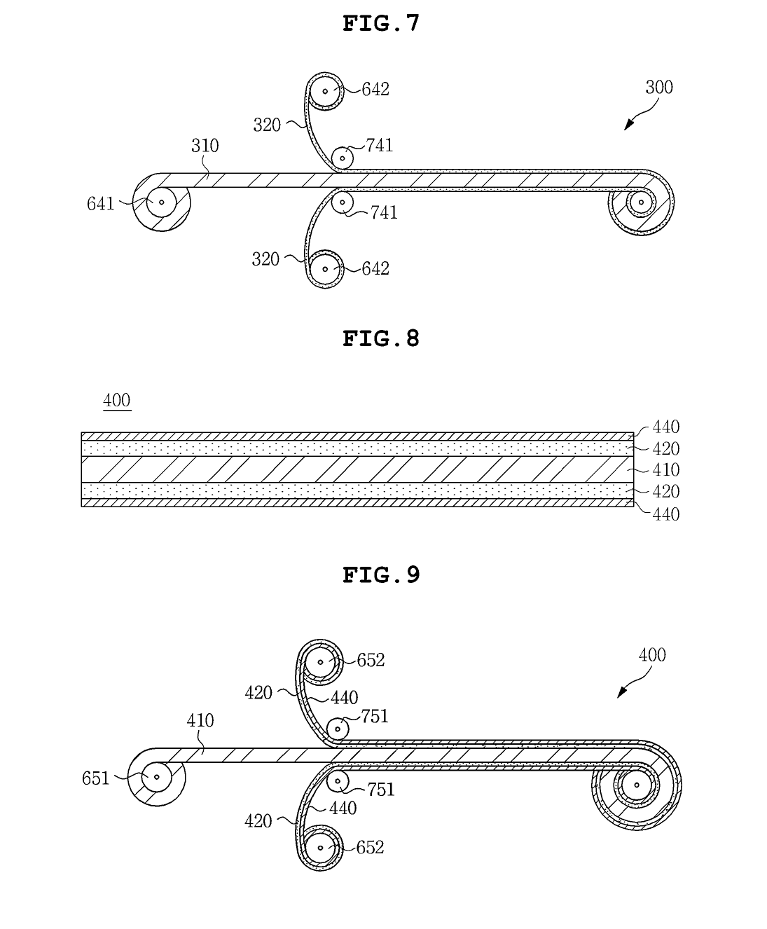

FIG. 7 is an illustrative view showing a method of manufacturing a core substrate according to the third preferred embodiment of the present invention.

Referring to FIG. 7, the core substrate 300 according to the third preferred embodiment of the present invention may be formed using a roll-to-roll device.

The roll-to-roll device according to the preferred embodiment of the present invention may include a first supplying roller 641, a second supplying roller 642, and a first compressing roller 741.

First, the glass substrate 310 may be supplied by the first supplying roller 641. The glass substrate 310 is a glass plate having flexibility.

The glass substrate 310 may be continuously supplied in the roll-to-roll device by the first supplying roller 641.

After the glass substrate 310 is supplied by the first supplying roller 641, the primer layer 320 may be supplied by the second supplying roller 642. Here, the primer layer 320 may be supplied onto at least one of one surface and the other surface of the glass substrate 310. According to the preferred embodiment of the present invention, the second supplying roller 642 may supply the primer layers 320 onto both surfaces of the glass substrate 310.

After the primer layer 320 is supplied onto the glass substrate 310, it may be compressed onto the glass substrate 310. The compression of the primer layer 320 onto the glass substrate 310 may be performed by the first compressing roller 741. The core substrate 300 in which the primer layer 320 is attached to the glass substrate 310 by the first compressing roller 741 may be formed.

The core substrate 300 according to the third preferred embodiment of the present invention including the glass substrate 310 and the primer layer 320 may be formed by the roll-to-roll device and the roll-to-roll method as described above.

As described above, the roll-to-roll device and the roll-to-roll method are used, thereby making it possible to improve adhesion between the core substrate 300 and the circuit patterns and manufacture the core substrate 300 according to the third preferred embodiment of the present invention having a small thickness deviation.

### Fourth Preferred Embodiment

FIG. 8 is an illustrative view showing a core substrate according to a fourth preferred embodiment of the present invention.

Referring to FIG. 8, the core substrate 400 may be configured to include a glass substrate 410, a primer layer 420, and a protective layer 440.

The glass substrate 410 according to the fourth preferred embodiment of the present invention may have flexibility. Since the glass substrate 410 has the flexibility, when a photosensitive insulating layer 430 is formed on the glass substrate 410, a roll-to-roll method may be used. The glass substrate 410 may serve to insulate between circuit patterns (not shown) to be formed later. Rigidity of the glass substrate 410 is high and a deformation degree thereof depending on temperature and humidity changes is low. Therefore, warpage of a printed circuit board including the core substrate 400 and a build-up layer formed on the core substrate 400 may be decreased by the glass substrate 410. In addition, since the glass substrate 410 has flexibility, it has low brittleness, such that it is hardly broken by external impact. Further, the flexible glass substrate 410 may be applied to a printed circuit board having a curved surface.

The primer layer 420 may be formed on at least one of one surface and the other surface of the glass substrate 410. Although the case in which the primer layers 420 are formed on both surfaces of the glass substrate 410 has been described in the fourth preferred embodiment of the present invention, the present invention is not limited thereto. That is, the primer layer 420 may also be formed on only one of one surface and the other surface of the glass substrate 410. Since the primer layer 420 has excellent adhesion, when circuit patterns will be formed later on the core substrate 400, adhesion between the core substrate 400 and the circuit patterns (not shown) may be improved.

The protective layer 440 may be formed on one surface or a lower surface of the primer layer 420 formed on the glass substrate 410. According to the preferred embodiment of the present invention, the protective layer 440 may have a surface roughness smaller than that of the primer layer 420. The surface roughness of the primer layer 420 may be decreased by the protective layer 440 having the small surface roughness as described above. Therefore, when a process of removing the protective layer 440 and forming circuit patterns (not shown) on the primer layer 420 will be performed later, fine circuit patterns may be implemented by the small surface roughness. For example, the protective layer 440 may be formed of a polyimide film or a PET film. However, a material of the protective layer 440 is not limited thereto, but may be easily changed and applied by those skilled in the art as long as it may protect the primer layer 420. According to the preferred embodiment of the present invention, damage to the core substrate 400 due to a process to be performed later or foreign materials may be prevented by the protective layer 440.

FIG. 9 is an illustrative view showing a method of manufacturing a core substrate according to the fourth preferred embodiment of the present invention.

Referring to FIG. 9, the core substrate 400 according to the fourth preferred embodiment of the present invention may be formed using a roll-to-roll device.

The roll-to-roll device according to the preferred embodiment of the present invention may include a first supplying roller 651, a second supplying roller 652, and a first compressing roller 751.

First, the glass substrate 410 may be supplied by the first supplying roller 651. The glass substrate 410 is a glass plate having flexibility.

The glass substrate 410 may be continuously supplied in the roll-to-roll device by the first supplying roller 651.

After the glass substrate 410 is supplied by the first supplying roller 651, the primer layer 420 may be supplied by the second supplying roller 652. Here, the primer layer 420 may be supplied onto at least one of one surface and the other surface of the glass substrate 410. According to the preferred embodiment of the present invention, the second supplying rollers 652 may be positioned on both surfaces of the glass substrate 410 to supply the primer layers 420.

In the preferred embodiment of the present invention, the protective layer 440 may be provided on one surface or the other surface of the primer layer 420. The protective layer 440 may prevent the primer layer 420 from being damaged due to a process to be performed later or foreign materials. According to the preferred embodiment of the present invention, the protective layer 440 may have a surface roughness smaller than that of the primer layer 420. The protective layer 440 having the small surface roughness may be attached to the primer layer 420 to allow the primer layer 420 to have a small surface roughness. Therefore, when circuit patterns will be formed later, fine circuit patterns may be implemented by the small surface roughness of the primer layer 420. The primer layer 420 according to the fourth preferred embodiment of the present invention may be formed beneath the protective layer 440 by a casting method.

For example, the protective layer 440 may be formed of a polyimide film or a PET film. However, a material of the protective layer 440 is not limited thereto, but may be easily changed and applied by those skilled in the art as long as it may protect the primer layer 420. The protective layer 440 may be formed on an opposite surface to a surface of the primer layer 420 contacting the glass substrate 410.

After the primer layer 420 having the protective layer 440 formed thereon is supplied onto the glass substrate 410, the protective layer 440 and the primer layer 420 may be compressed onto the glass substrate 410. The compression of the protective layer 440 and the primer layer 420 onto the glass substrate 410 may be performed by the first compressing roller 751.

As described above, the roll-to-roll device and the roll-to-roll method are used, thereby making it possible to improve adhesion between the core substrate 400 and the circuit patterns and manufacture the core substrate 400 according to the fourth preferred embodiment of the present invention having a small thickness deviation.

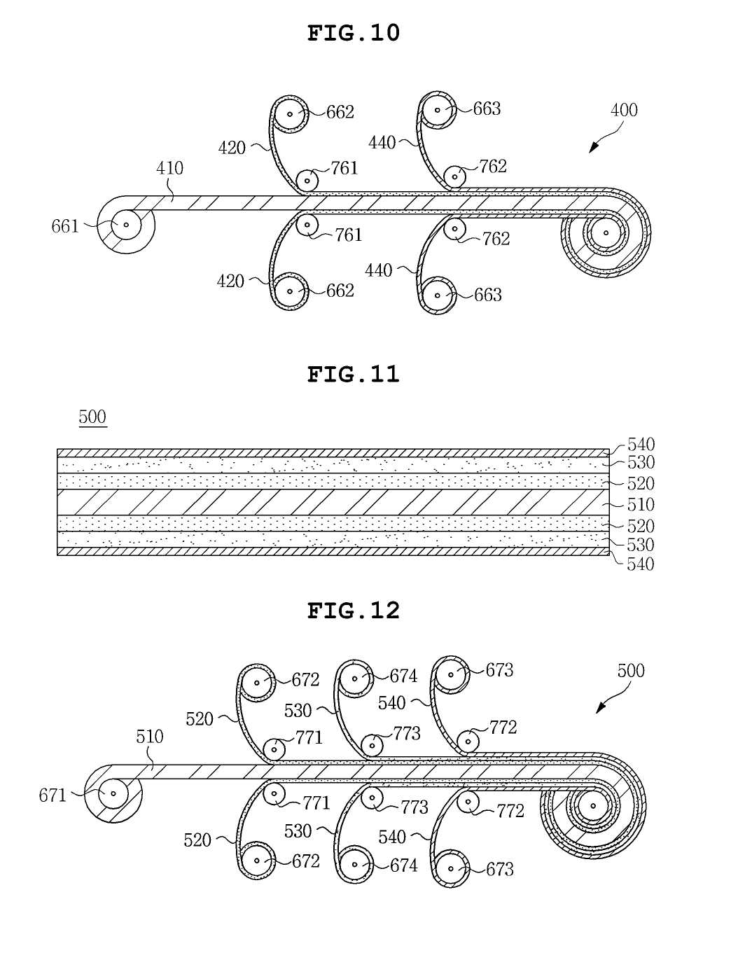

FIG. 10 is an illustrative view showing another method of manufacturing a core substrate according to the fourth preferred embodiment of the present invention.

Referring to FIG. 10, the core substrate 400 according to the fourth preferred embodiment of the present invention may be formed using a roll-to-roll device.

The roll-to-roll device according to the preferred embodiment of the present invention may include a first supplying roller 661, a second supplying roller 662, a third supplying roller 663, a first compressing roller 761, and a second compressing roller 762.

First, the glass substrate 410 may be supplied by the first supplying roller 661. The glass substrate 410 is a glass plate having flexibility.

The glass substrate 410 may be continuously supplied in the roll-to-roll device by the first supplying roller 661.

After the glass substrate 410 is supplied by the first supplying roller 661, the primer layer 420 may be supplied by the second supplying roller 662. Here, the primer layer 420 may be supplied onto at least one of one surface and the other surface of the glass substrate 410. According to the preferred embodiment of the present invention, the second supplying rollers 662 may be positioned on both surfaces of the glass substrate 410 to supply the primer layers 420.

After the primer layer 420 is supplied onto the glass substrate 410, it may be compressed onto the glass substrate 410. The compression of the primer layer 420 onto the glass substrate 410 may be performed by the first compressing roller 761.

After the primer layer 420 is compressed onto the glass substrate 410, the protective layer 440 may be provided on one surface or the other surface of the primer layer 420. The protective layer 440 may be supplied by the third supplying roller 663. The protective layer 440 may prevent the primer layer 420 from being damaged due to a process to be performed later or foreign materials. According to the preferred embodiment of the present invention, the protective layer 440 may have a surface roughness smaller than that of the primer layer 420. The protective layer 440 having the small surface roughness may be attached to the primer layer 420 to allow the primer layer 420 to have a small surface roughness. Therefore, when circuit patterns will be formed later, fine circuit patterns may be implemented by the small surface roughness of the primer layer 420. For example, the protective layer 440 may be formed of a polyimide film or a PET film. However, a material of the protective layer 440 is not limited thereto, but may be easily changed and applied by those skilled in the art as long as it may protect the primer layer 420.

When the protective layer 440 is supplied onto one surface or the other surface of the primer layer 420, the protective layer 440 may be compressed onto the primer layer 420 by the second compressing roller 762.

As described above, the roll-to-roll device and the roll-to-roll method are used, thereby making it possible to improve adhesion between the core substrate 400 and the circuit patterns and manufacture the core substrate 400 according to the fourth preferred embodiment of the present invention having a small thickness deviation.

### Fifth Preferred Embodiment

FIG. 11 is an illustrative view showing a core substrate according to a fifth preferred embodiment of the present invention.

Referring to FIG. 11, the core substrate 500 may be configured to include a glass substrate 510, a primer layer 520, a photosensitive insulating layer 530, and a protective layer 540.

The glass substrate 510 may have flexibility. Since the glass substrate 510 has the flexibility, when the photosensitive insulating layer 530 is formed on the glass substrate 510, a roll-to-roll method may be used. In addition, the glass substrate 510 may be a glass plate through which light is not transmitted. The glass substrate 510 may be hardly transparent so as not to transmit the light therethrough when an exposure process will be performed later in order to pattern the photosensitive insulating layer 530. The glass substrate 510 may serve to insulate between circuit patterns (not shown) to be formed later. Rigidity of the glass substrate 510 is high and a deformation degree thereof depending on temperature and humidity changes is low. Therefore, warpage of a printed circuit board including the core substrate 500 and a build-up layer formed on the core substrate 500 may be decreased by the glass substrate 510. In addition, since the glass substrate 510 has flexibility, it has low brittleness, such that it is hardly broken by external impact. Further, the flexible glass substrate 510 may be applied to a printed circuit board having a curved surface.

The primer layer 520 may be formed on at least one of one surface and the other surface of the glass substrate 510. Although the case in which the primer layers 520 are formed on both surfaces of the glass substrate 510 has been described in the fifth preferred embodiment of the present invention, the present invention is not limited thereto. That is, the primer layer 520 may also be formed on only one of one surface and the other surface of the glass substrate 510.

Since the primer layer 520 has excellent adhesion, when circuit patterns will be formed later on the core substrate 500, adhesion between the core substrate 500 and the circuit patterns (not shown) may be improved.

The photosensitive insulating layer 530 may be formed on at least one of one surface and the other surface of the primer layer 520. The photosensitive insulating layer 530 may be a positive type photosensitive insulating layer in which a region subjected to exposure is decomposed. Alternatively, the photosensitive insulating layer 530 may be a negative type photosensitive insulating layer in which a region subjected to exposure is cured. In the core substrate 500 according to the fifth preferred embodiment of the present invention, circuit patterns are formed later in the photosensitive insulating layer 530 in a form in which they are buried in the photosensitive insulating layer 530, thereby making it possible to decrease a defect such as undercut of the circuit pattern, separation of the circuit pattern, or the like.

The protective layer 540 may be formed on one surface or the other surface of the photosensitive insulating layer 530. The protective layer 540 may protect the photosensitive insulating layer 530 from a stab due to a process to be performed later or foreign materials. According to the preferred embodiment of the present invention, a surface of the protective layer 540 bonded to the photosensitive insulating layer 530 may have a surface roughness smaller than that of the photosensitive insulating layer 530. The surface roughness of the photosensitive insulating layer 530 may be decreased by the protective layer 540 having the small surface roughness. Therefore, when a process of removing the protective layer 540 and forming circuit patterns will be performed later, fine circuit patterns may be implemented by the small surface roughness of the photosensitive insulating layer 530. For example, the protective layer 540 may be formed of a polyimide film or a PET film. However, a material of the protective layer 540 is not limited thereto, but may be easily changed and applied by those skilled in the art as long as it may protect the photosensitive insulating layer 530.

FIG. 12 is an illustrative view showing a method of manufacturing a core substrate according to the fifth preferred embodiment of the present invention.

Referring to FIG. 12, the core substrate 500 according to the fifth preferred embodiment of the present invention may be formed using a roll-to-roll device.

The roll-to-roll device according to the preferred embodiment of the present invention may include a first supplying roller 671, a second supplying roller 672, a third supplying roller 673, a fourth supplying roller 674, a first compressing roller 771, a second compressing roller 772, and a third compressing roller 773.

First, the glass substrate 510 may be supplied by the first supplying roller 671. The glass substrate 510 is a glass plate having flexibility. In addition, the glass substrate 510 may be a glass plate having low transparency. The glass substrate 510 may be hardly transparent so as not to transmit the light therethrough when an exposure process will be performed later in order to pattern the photosensitive insulating layer 530.

The glass substrate 510 may be continuously supplied in the roll-to-roll device by the first supplying roller 671. According to the preferred embodiment of the present invention, since the glass substrate 510 is flexible, it is appropriate for a roll-to-roll process.

After the glass substrate 510 is supplied by the first supplying roller 671, the primer layer 520 may be supplied by the second supplying roller 672. Here, the primer layer 520 may be supplied onto at least one of one surface and the other surface of the glass substrate 510. According to the preferred embodiment of the present invention, the second supplying roller 672 may supply the primer layers 520 onto both surfaces of the glass substrate 510.

After the primer layer 520 is supplied onto the glass substrate 510, it may be compressed onto the glass substrate 510. The compression of the primer layer 520 onto the glass substrate 510 may be performed by the first compressing roller 771.

After the primer layer 520 is compressed onto the glass substrate 510, the photosensitive insulating layer 530 may be supplied onto one surface or the other surface of the primer layer 520. The photosensitive insulating layer 530 may be supplied onto the primer layer 520 by the fourth supplying roller 674.

After the photosensitive insulating layer 530 is supplied by the fourth supplying roller 674, it may be compressed onto the primer layer 520. The compression of the photosensitive insulating layer 530 onto the primer layer 520 may be performed by the third compressing roller 773.

After the photosensitive insulating layer 530 is compressed onto the primer layer 520, the protective layer 540 may be supplied onto one surface or the other surface of the photosensitive insulating layer 530. The protective layer 540 may be supplied by the third supplying roller 673. The protective layer 540 may prevent the photosensitive insulating layer 530 from being damaged due to a process to be performed later or foreign materials. According to the preferred embodiment of the present invention, the protective layer 540 may have a surface roughness smaller than that of the photosensitive insulating layer 530. The protective layer 540 having the small surface roughness may be attached to the photosensitive insulating layer 530 to allow the photosensitive insulating layer 530 to have a small surface roughness. For example, the protective layer 540 may be formed of a polyimide film or a PET film. However, a material of the protective layer 540 is not limited thereto, but may be easily changed and applied by those skilled in the art as long as it may protect the photosensitive insulating layer 530.

When the protective layer 540 is supplied onto one surface or the other surface of the photosensitive insulating layer 530, the protective layer 540 may be compressed onto the photosensitive insulating layer 530 by the second compressing roller 772.

Although the case in which the protective layer 540 is formed on the photosensitive insulating layer 530 by the third supplying roller 673 and the second compressing roller 772 has been described in the fifth preferred embodiment of the present invention, the present invention is not limited thereto.

For example, the protective layer 540 may be formed on the photosensitive insulating layer 530 in advance. In this case, the photosensitive insulating layer 530 may be formed beneath the protective layer 540 by a casting method.

The photosensitive insulating layer 530 having the protective layer 540 formed thereon as described above may be supplied onto the primer layer 520 by the fourth supplying roller 674 and the third compressing roller 773. That is, the protective layer 540 is formed on the photosensitive insulating layer 530 in advance, thereby making it possible to simultaneously form the photosensitive insulating layer 530 and the protective layer 540 on the primer layer 520.

As described above, the roll-to-roll device and the roll-to-roll method are used, thereby making it possible to easily form fine circuit patterns, improve adhesion between the core substrate 500 and the circuit patterns, and form the core substrate 500 according to the fifth preferred embodiment of the present invention having a small thickness deviation.

With the core substrate and the method of manufacturing the same according to the preferred embodiments of the present invention, the warpage of the printed circuit board including the core substrate and the build-up layer formed on the core substrate may be decreased by the glass substrate having the flexibility. In addition, with the core substrate and the method of manufacturing the same according to the preferred embodiments of the present invention, the glass substrate has the flexibility, such that the core substrate is hardly broken by external impact and may be applied to a printed circuit board having a curved surface. Further, with the core substrate and the method of manufacturing the same according to the preferred embodiments of the present invention, the adhesion between the core substrate and the circuit pattern may be improved by the primer layer, and the undercut of the circuit pattern, the separation of the circuit pattern, and the like, may be decreased by the photosensitive insulating layer.

With the core substrate and the method of manufacturing the same according to the preferred embodiments of the present invention, the fine circuit patterns may be formed.

With the core substrate and the method of manufacturing the same according to the preferred embodiments of the present invention, generation of a defect such as separation of a circuit pattern may be decreased.

With the core substrate and the method of manufacturing the same according to the preferred embodiments of the present invention, a thickness deviation of the core substrate may be decreased.

With the core substrate and the method of manufacturing the same according to the preferred embodiments of the present invention, warpage of the core substrate may be decreased.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A core substrate comprising:
a glass substrate having flexibility; and
a photosensitive insulating layer formed on at least one of one surface and the other surface of the glass substrate.

2. The core substrate as set forth in claim 1, wherein the glass substrate does not transmit light therethrough.

3. The core substrate as set forth in claim 1, further comprising a protective layer formed on one surface or the other surface of the photosensitive insulating layer.

4. The core substrate as set forth in claim 1, further comprising a primer layer formed between the glass substrate and the photosensitive insulating layer.

5. A method of manufacturing a core substrate, comprising:
supplying a glass substrate having flexibility by a first supplying roller;
supplying a photosensitive insulating layer onto at least one of one surface and the other surface of the glass substrate by a second supplying roller; and
compressing the photosensitive insulating layer onto the glass substrate by a first compressing roller.

6. The method as set forth in claim 5, wherein in the supplying of the glass substrate, the glass substrate does not transmit light therethrough.

7. The method as set forth in claim 5, wherein in the supplying of the photosensitive insulating layer, the photosensitive insulating layer includes a protective layer formed on one surface or the other surface thereof.

8. The method as set forth in claim 7, wherein the photosensitive insulating layer is formed beneath the protective layer by a casting method.

9. The method as set forth in claim 5, further comprising, after the compressing of the photosensitive insulating layer onto the glass substrate, supplying a protective layer onto one surface or the other surface of the photosensitive insulating layer by a third supplying roller.

10. The method as set forth in claim 9, further comprising, after the supplying of the protective layer onto one surface or the other surface of the photosensitive insulating layer, compressing the protective layer onto the photosensitive insulating layer by a second compressing roller.

11. The method as set forth in claim 5, further comprising, after the supplying of the glass substrate, supplying a primer layer onto one surface or the other surface of the glass substrate by a fourth supplying roller.

12. The method as set forth in claim 11, further comprising, after the supplying of the primer layer, compressing the primer layer onto the glass substrate by a third compressing roller.

13. A core substrate comprising:
a glass substrate having flexibility; and
a primer layer formed on at least one of one surface and the other surface of the glass substrate.

14. The core substrate as set forth in claim 13, wherein the glass substrate does not transmit light therethrough.

15. The core substrate as set forth in claim 13, further comprising a protective layer formed on one surface or the other surface of the primer layer.

16. The core substrate as set forth in claim 13, further comprising a photosensitive insulating layer formed on one surface or the other surface of the primer layer.

17. The core substrate as set forth in claim 16, further comprising a protective layer formed on one surface or the other surface of the photosensitive insulating layer.

18. A method of manufacturing a core substrate, comprising:
supplying a glass substrate having flexibility by a first supplying roller;
supplying a primer layer onto at least one of one surface and the other surface of the glass substrate by a second supplying roller; and
compressing the primer layer onto the glass substrate by a first compressing roller.

19. The method as set forth in claim 18, wherein in the supplying of the glass substrate, the glass substrate does not transmit light therethrough.

20. The method as set forth in claim 18, wherein in the supplying of the primer layer, the primer layer includes a protective layer formed on one surface or the other surface thereof.

21. The method as set forth in claim 20, wherein the primer layer is formed beneath the protective layer by a casting method.

22. The method as set forth in claim 18, further comprising, after the compressing of the primer layer onto the glass substrate, supplying a protective layer onto one surface or the other surface of the primer layer by a third supplying roller.

23. The method as set forth in claim 22, further comprising, after the supplying of the protective layer onto one surface or the other surface of the primer layer, compressing the protective layer onto the primer layer by a second compressing roller.

24. The method as set forth in claim 18, further comprising, after the compressing of the primer layer onto the glass substrate, supplying a photosensitive insulating layer onto one surface or the other surface of the primer layer by a fourth supplying roller.

25. The method as set forth in claim 24, further comprising, after the supplying of the photosensitive insulating layer, compressing the photosensitive insulating layer onto the primer layer by a third compressing roller.
